(19) United States
(12) Patent Application Publication
(10) Pub. No.: US 2005/0085084 A1
(43) Pub. Date: Apr. 21, 2005

(54) Method of fabricating copper metallization on backside of gallium arsenide devices

(76) Inventors: Edward Yi Chang, Hsinchu City (TW); Cheng-Shih Lee, Gueishan Township (TW)

Correspondence Address: RABIN & BERDO, P.C.;Suite 500, 1101 14th Street, N.W., Washington, DC, 20005, US

(21) Appl. No.: 10/685,600

(22) Filed: Oct. 16, 2003

(51) Int. Cl. H01L 21/302; H01L 21/461

(52) U.S. Cl. 438/706

(57) ABSTRACT

A bi-level structure based on copper metallization technique has been applied to backside of gallium arsenide (GaAs) devices. The foundation where the structure stands on is device substrate backside, on which a layer of diffusion barrier is deposited first, and to the top of it, a layer of copper metallization is plated to enhance device performance. The barrier layer can be selected from tungsten (W), tungsten nitride (WN), or titanium tungsten nitride (TiWN) by sputtering or evaporating, which effectively prevents copper from diffusing into GaAs substrate. The layer of copper metallization, formed by employing anyone of sputtering, evaporating, or electroplating, proves to offer attractive thermal and electrical conductivity and mechanical strength and the like. Moreover, these characteristic improvements coupled with a fascinating part, low cost, would benefit and motivate global GaAs fabs.

### FIELD OF THE INVENTION

The present invention relates generally to a method of backside metallization in semiconductor devices and more particularly relates to a backside metal process transition from gold to copper for gallium arsenide (GaAs) devices, and a selection of refractory metals or alloys as diffusion barriers for copper metallization.

### BACKGROUND OF THE INVENTION

As IBM succeeded in introducing copper in its wafer processing, the integration of copper metallization process in silicon chips fabrication becomes a hot topic among semiconductor community. Copper is taken advantage of its great resistance to electromigration and low electrical resistance by metallization process of chips fabrication. However, the diffusion of copper into silicon is fast, and the interactions between copper and silicon is faster than that between aluminum and silicon. Furthermore, there are some other reasons, for instance, no available dry etching process for copper, and other difficulties in adapting copper in the semiconductor manufacturing processes, which altogether makes aluminum the preferred choice of interconnect metallization. As the innovative technique of copper metallization, the Damacene approaches, and accompanying processes successfully being developed, copper was emerging and taking the place of aluminum as the preferred metallization material in silicon wafer fabrication. There are quite a few silicon chipmakers that have already replaced aluminum with copper in their chip metallization process, while some fabs using tantalum (Ta) or tantalum nitride (TaN) as barrier material. Meanwhile, there isn't an available copper metallization process for the fabrication of GaAs FETs.

GaAs FETs and MMICs are employing gold as metallization material for their interconnect lines, passive devices, and contacts, where interconnects and contacts are thicker than 2-3 μm and obviously consume lot more gold, which is costly. Furthermore, GaAs has poor thermal conductivity, which limits the thickness of power FETs in about 2 to 5 mils for better heat dissipation, but side-effect is too brittle. As copper adopted as material for GaAs device backside metallization, mechanical strength and heat dissipation are substantially improved.

Traditionally, backside metallization process was done by mechanically thinned to approximately 100 μm, followed by formation of backside vias and deposition of layers of titanium tungsten (TiW) and gold (Au) for grounding, dissipating, and strengthening purposes. Copper has superior thermal and electrical conductivity and pricing over gold. However, copper is a real fast diffuser in GaAs as it is in Si and further forms deep trapped center, which not only degrading device electrical behavior, but creating contamination to the devices. Moreover, copper metallization is not available in GaAs industry yet. As we have seen, copper metallization for GaAs devices has attracted great attention and will do as chip dimension getting smaller.

The following information is a comparative analysis between the present invention and the existing patents on copper metallization published in Taiwan, Republic of China.

Taiwanese Pat. No. 465069 issued Mar. 11, 2002, discloses a focusing on copper metallization in silicon frontside processing. Its barrier is formed by depositing tantalum (Ta), tantalum nitride (TaN), and titanium nitride (TiN) successively on silicon substrate; therefore, several layers are required by diffusion barrier in this patent, whereas only one barrier layer in said invention. The barrier material in said invention is also different from this patent. As a result, said invention has simple process and better efficiency in preventing copper diffusion. In addition, the other similar patent, Taiwanese Pat. No. 465069, is for silicon IC fabrication, while said invention for GaAs.

Taiwanese Pat. No. 436995 issued May 3, 2001, discloses manufacturing a barrier layer in copper process. The barrier is formed by depositing titanium (Ti) and titanium nitride (TiN) through Ion Beam Sputter Deposition (IBSD) or Metal Organic Vapor Epitax (MOCVD) process. Radio frequency (RF) for IBSD process is 13.56 MHz, while operating power is between 0 to 300 W. A thin copper seed layer is required by the IBSD, followed by a thicker copper layer through electroplating. The barrier materials for said invention and this patent are different. Moreover, its barrier deposition process adopted by this invention will fail to deposit metal on the entire via wall.

Taiwanese Pat. No. 280002 issued Jul. 1, 1996, takes tantalum nitride (TaN) as its barrier material and Metal Organic Chemical Vapor Deposition (MOCVD) as its deposition process. The sputtering is adopted as deposition process to form barrier layer in said invention, where copper and barrier layer can be sequentially deposited by the sputter in the same vacuum chamber. This is especially beneficial to the fabrication industry.

The major disadvantage of gold metallization is its price. Gold, same as copper, has high resistance to electromigration but lower resistivity. It has been employed extensively in GaAs device fabrication, subject to its high electrical conductivity and relative chemical inertness. However, its relatively lower thermal conductivity and absolutely high cost makes copper advantageous in taking its place. Copper has difficulty in using as direct contact material in GaAs chip fabrication; besides, copper metallization process for GaAs device has not matured yet, and it now still in developing. As a result, the present invention tries to complement recent technological barrier encountered in GaAs copper process, by offering a backside copper metallization fabrication method. This method is based on taking copper as metal for GaAs device backside metallization, and on a barrier layer to prevent copper from diffusion, which can be done by traditional sputtering methods. The GaAs chips, fabricated by this novel but handy process, has proved to have better device performances than conventional ones, and which are believed to be beneficial to GaAs chips fabrication.

### SUMMARY OF THE INVENTION

The object of this invention is to employ ways of deposition: sputtering, evaporation, or electroplating to fabricate backside copper metallization for GaAs devices, where the barrier thin film is made of refractory metals or alloys: tungsten (W), tungsten nitride (WN), or titanium tungsten nitride (TiWN) which will effectively prevent copper from diffusing into GaAs substrate. Through the copper metallization process, further advantages in featuring improvements such as heat dissipation, mechanical strength, conductivity, and device characteristics and reliability are achieved. Moreover, the novel but handy process is especially beneficial to the GaAs industry.

The present invention is realized by the following implementation—a process of copper metallization on backside of GaAs devices is implemented by depositing a thin film of W, WN, or TiWN on backside of GaAs wafer as a barrier layer, followed by depositing a layer of copper as the metal for metallization process. By means of the barrier layer, copper is prevented from diffusing into GaAs substrate; furthermore, copper has better metallic characteristics to improve device performances such as heat dissipation, mechanical strength, and electrical conductivity and the like.

### BRIEF DESCRIPTION OF THE DRAWINGS

The present invention featuring its novelty, can be readily understood by reading the following detailed description of the preferred embodiments, with reference made to the accompanying drawings, wherein:

FIG. 1 is a cross-sectional view of GaAs device, schematically showing the copper metallization on device backside with via holes; and

FIG. 2 is a plot of x-ray diffraction analysis with reference to a set of temperatures after annealing.

### DETAILED DESCRIPTION OF THE INVENTION

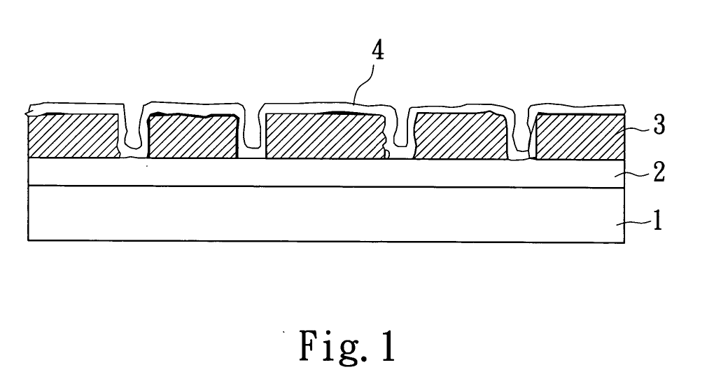

FIG. 1 is a cross-sectional view of the present invention. As is shown, the device is first thinned mechanically to a thickness of 100 μm, followed by formation of backside via holes which are etched by inductively coupled plasma (ICP) technique. Sloping the via profile will facilitate copper metallization. A thickness of 40 to 100 nm of a barrier layer is then deposited on by sputtering or evaporation. Finally, the copper metallization process starts with a thin copper seed layer deposited by sputtering and, followed by desired thickness (2 to 10 μm) of copper deposited by sputtering or electroplating. The device is shown in FIG. 1, where the apparatus comprises a Quantz 1 as carrier, wax 2 which is used to mount the chip on the carrier, a chip 3, and a barrier layer and metallized copper thereon 4.

The present invention is now further realized in a particularly advantageous embodiment, which is by illustrating an example of fabricating copper metallization process on backside of a GaAs metal semiconductor field effect transistor (MESFET), to enable the awareness to those skilled in the art and for them to easily follow the functionality.

Prior to thin film deposition process, the GaAs MESFET substrate is clean with acetone and isoacetone for 5 minutes respectively, followed in a solution by a mixture of HF, H₂O₂, and H₂O—1:2:20 for 20 seconds, and again in a solution of HCL and H₂O—1:4 for 1 minute. When these pre-deposition cleaning steps are finished, tantalum nitride (TaN) is sputtered on 3-inch (100) GaAs substrate in a thickness of 40 nm. After that, a thickness of 2 to 10 nm thin film of copper (Cu) and a thickness of 10 nm thin film of TaN are successively sputtered on by a multitarget magnetron sputtering system operating under vacuum. The outmost TaN thin film is used for preventing Cu from oxidation and preventing oxygen from entering the film at high temperature annealing. TaN thin films are formed by sputtering through a reaction of tantalum (Ta) with a gaseous mixture—20% nitrogen (N₂) and 80% argon (Ar). Vacuum pressure of pre-sputtering is 2.6×10⁻⁵ Pa, while the operating pressure keeps at 0.8 Pa. Wafer is annealing at 400° C. to 600° C. for 30 minutes in Ar atmosphere.

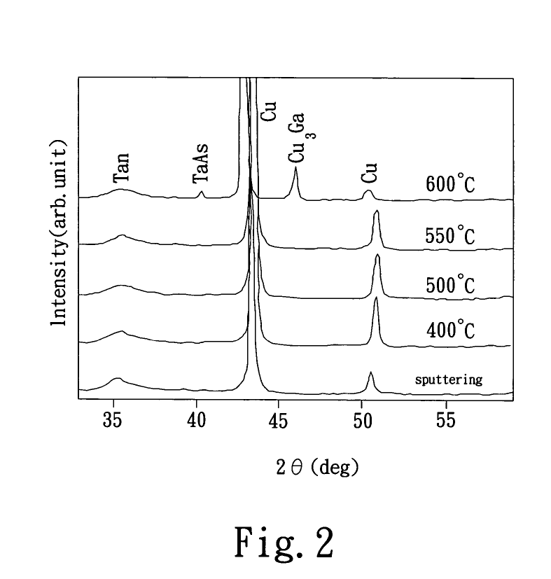

Tantalum nitride/copper/tantalum nitride/gallium arsenide (TaN/Cu/TaN/GaAs) stack is engaging x-ray diffraction analysis. A plot of x-ray diffraction analysis with regard to a set of temperatures after annealing is shown in FIG. 2, where the reference temperatures are set from the moment right after sputtering, 400° C., 500° C., 550° C., and 600° C. at annealing visualized in a bottom-up manner. FIG. 2 shows that diffraction peaks of TaN and Cu are clear until 550° C., which represents the inter-layers in Cu/TaN/GaAs structure are stable up to 550° C. At 600° C. of annealing, diffraction peaks of tantalum arsenide (TaAs), copper gallium compound (Cu₃Ga), and copper arsenide (Cu₂As) appear, which means tantalum (Ta) reacts with GaAs at 600° C. However, diffraction peaks of TaN and Cu still exist after 600° C. of annealing, which means reactions and diffusions are not an overall phenomenon.

Table 1 and Table 2 are parameters of a 150 μm GaAs device in a increment and incremental percentage, under having copper metallization (Table 1) and without copper metallization (Table 2), and measured at moments before and after annealing. Parameters include: saturated drain-source current (I_{dss}), transconductance (Gₘ), and pinch-off voltage (Vₚ), where I_{dss} measured at drain-source voltage V_{ds}=2V, Gₘ measured at gate-source voltage V_{gs}=0V and V_{ds}=2V, and Vₚ measured at drain-source current I_{ds}=150 mA. Incremental percentages of I_{dss}, Gₘ, and Vₚ based on having copper metallization are 1.60%, 0.73%, and 1.35%, which are close to the values: 3.93%, 3.03%, and 3.00% of without copper metallization. The fact of this result represents that copper didn't diffuse into GaAs active regions for fatal destroy.

TABLE 1
150 μm copper metallization device

| | |
|---|---|
| Increment | Incremental (%) |

| | | | |
|---|---|---|---|
| ΔI_{dss} | 0.51 | ΔI_{dss}/I_{dss} | 1.60 |
| (Ma) | | | |
| ΔGₘ | 0.75 | ΔGₘ/Gₘ | 0.73 |
| (V_{gs} = 0 V) | | | |
| (mS/mm) | | | |
| ΔV_{P} | 0.04 | ΔV_{P}/V_{P} | 1.35 |
| (V) | | | |

TABLE 2
150 μm device without copper metallization

| | |
|---|---|
| Increment | Incremental (%) |

| | | | |
|---|---|---|---|
| ΔI_{dss} | 0.91 | ΔI_{dss}/I_{dss} | 3.93 |
| (Ma) | | | |
| ΔGₘ | 3.07 | ΔGₘ/Gₘ | 3.03 |
| (V_{gs} = 0 V) | | | |
| (mS/mm) | | | |
| ΔV_{P} | 0.08 | ΔV_{P}/V_{P} | 3.00 |
| (V) | | | |

The radio frequency RF characteristics under thermal stability tests for device with or without copper metallization are shown in Table 3 and Table 4, where the tests are measured at V_{ds}=7V and I_{ds}=100 mA. The 1 μm×10 mm copper metallization device is characterized by following parameters: maximum frequency of oscillation (fₘₐₓ), maximum power gain (Gₘₐₓ), and unilateral power gain (U_{G}). The device is tested under the conditions of heating at 300° C. and annealing for 2 hours, and the increments of measured data: Δfₘₐₓ, ΔGₘₐₓ, and ΔU_{G} are 0.34 GHz, 0.38 dB, and 0.69 dB respectively for device having copper metallization, while its counterpart, without copper metallization, are −0.4 GHz, 0.1 dB, and 0.56 dB. The test data shows incremental (or decremental) values measured by with and without copper metallization are close; therefore, changes in RF electrical characteristics are subject to thermal effects, and copper metallization would not cause disaster in device characteristics.

TABLE 3
1 μm × 10 mm copper metallization device

| Device | Before | After | Increment | |
|---|---|---|---|---|
| parameters | annealing | annealing | or decrement | |
| fₘₐₓ (GHz) | 10.37 | 10.03 | Δfₘₐₓ (GHz) | 0.34 |
| Below 0.9 GHz | 17.24 | 16.86 | Below 0.9 GHz | 0.38 |
| Gₘₐₓ (dB) | | | ΔGₘₐₓ (dB) | |
| Below 0.9 GHz | 19.00 | 18.31 | Below 0.9 GHz | 0.69 |
| U_{G} (dB) | | | ΔU_{G} (dB) | |

TABLE 4
1 μm × 10 mm device without copper metallization

| Device | Before | After | Increment | |
|---|---|---|---|---|
| parameters | annealing | annealing | or decrement | |
| fₘₐₓ (GHz) | 9.6 | 10 | Δfₘₐₓ (GHz) | −0.4 |
| Below 0.9 GHz | 17.36 | 17.26 | Below 0.9 GHz | 0.1 |
| Gₘₐₓ (dB) | | | ΔGₘₐₓ (dB) | |
| Below 0.9 GHz | 19.86 | 19.30 | Below 0.9 GHz | 0.56 |
| U_{G} (dB) | | | ΔU_{G} (dB) | |

Through the realization of the present invention, a method of fabricating copper metallization on backside of GaAs devices, several promising features are shown as following:
1. Combining attractive thermal conductivity and power, with improved heat dissipation, mechanical strength and electrical conducting, a low cost, improved characteristics and reliable device can be achieved.
2. A barrier thin film deposited by metals or alloys: tungsten (W), tungsten nitride (WN), or titanium tungsten nitride (TiWN), will effectively prevent copper from diffusing into GaAs substrate to impact device characteristics.
3. The present invention employs only one film of barrier, which eases the process and enhances the prevention of copper diffusion.
4. The present invention adopts the sputtering method, where the barrier and Cu layer are deposited in the same vacuum chamber.

It is thought that the method of the present invention will be understood from the foregoing description. While the present invention has been described with reference to its preferred embodiment, it is to be noted that variations or alternative embodiments may suggest themselves to those of skill in the art, upon a reading hereof. Therefore, the following claims should be interpreted broadly to include any such equivalents.

1. A method of fabricating copper metallization on backside of GaAs devices, comprising:
a substrate, thereon via holes are fabricated;
a diffusion barrier layer formed on said backside of said substrate; and
a copper metallization layer formed on said barrier layer.

2. A method as claimed in claim 1, wherein said substrate is made of gallium arsenide (GaAs).

3. A method as claimed in claim 1, wherein said via holes can be fabricated by etching through a use of inductively coupled plasma (ICP).

4. A method as claimed in claim 1, wherein said diffusion barrier layer can be deposited by sputtering on said backside of said substrate.

5. A method as claimed in claim 1, wherein said diffusion barrier layer can be deposited by evaporating on said backside of said substrate.

6. A method as claimed in claim 1, wherein said diffusion barrier layer has a thickness of 40 to 100 nm.

7. A method as claimed in claim 1, wherein said diffusion barrier layer can be a thin film of tungsten (W).

8. A method as claimed in claim 1, wherein said diffusion barrier layer can be said thin film of tungsten nitride (WN).

9. A method as claimed in claim 1, wherein said diffusion barrier layer can be said thin film of titanium tungsten nitride (TiWN).

10. A method as claimed in claim 1, wherein said copper metallization layer can be deposited by said sputtering on said diffusion barrier layer.

11. A method as claimed in claim 1, wherein said copper metallization layer can be deposited by said evaporating on said diffusion barrier layer.

12. A method as claimed in claim 1, wherein said copper metallization layer can be deposited by electroplating on said diffusion barrier layer.

13. A method as claimed in claim 1, wherein said copper metallization layer has a thickness of 2 to 10 μm.
